(19) United States
(12) Patent Application Publication
(10) Pub. No.: US 2012/0240859 A1
(43) Pub. Date: Sep. 27, 2012

(54) WAFER SUSCEPTOR AND CHEMICAL VAPOR DEPOSITION APPARATUS

(75) Inventors: Weicheng Chen, Tainan (TW); Zonglin Lee, Tainan (TW); Hsinchuan Wang, Tainan (TW)

(73) Assignee: CHI MEI LIGHTING TECHNOLOGY CORP., Tainan City (TW)

(21) Appl. No.: 13/168,077

(22) Filed: Jun. 24, 2011

(30) Foreign Application Priority Data
Mar. 22, 2011 (TW) 100109747

(51) Int. Cl. C23C 16/458; B05C 13/00

(52) U.S. Cl. 118/730; 118/500

(57) ABSTRACT

A wafer susceptor and a chemical vapor deposition apparatus. In one embodiment, the chemical vapor deposition apparatus includes a chamber, a susceptor, a heater and a gas supply system. The susceptor is disposed within the chamber and is rotatable around a rotation axis, wherein an upper surface of the susceptor is suitable for carrying a plurality of wafers, and a middle region of a lower surface of the susceptor is set with a first cavity. The heater is disposed under the susceptor and is used to heat the wafers on the susceptor. The gas supply system is used to introduce a reactive gas into the chamber.

### CROSS-REFERENCE TO RELATED APPLICATIONS

This non-provisional application claims priority under 35 U.S.C. §119(a) on Patent Application No. 100109747 filed in Taiwan, R.O.C. on Mar. 22, 2011, the entire contents of which are hereby incorporated by reference.

### FIELD OF THE INVENTION

The present invention relates to a deposition apparatus, and more particularly to a chemical vapor deposition (CVD) apparatus.

### BACKGROUND OF THE INVENTION

Presently, in processes for manufacturing compound semiconductor devices, a Chemical Vapor Deposition (CVD) apparatus, such as a metal-organic CVD (MOCVD), is usually used for growing chips required. The existing CVD apparatuses are classified into vertical type and horizontal type according to different design forms of a reaction chamber. The vertical type CVD apparatus is such designed that a precursor required for deposition reaction is introduced to a position above chips in the reaction chamber in a manner of being vertical to the chip surface.

FIG. 1 is a schematic view of a conventional vertical type CVD apparatus. A CVD apparatus 100 includes a gas supply system 102, a reaction chamber 104, a susceptor 106, and a heater 108. The susceptor 106 is disposed in the reaction chamber 104, and an upper surface of the susceptor 106 may support a plurality of wafers. Furthermore, in order to heat the chips on the susceptor 106 evenly, the susceptor 106 is generally designed to be capable of rotating around a rotation axis 110 in the reaction chamber 104.

The heater 108 is disposed below the susceptor 106 in the reaction chamber 104, so as to heat the chips in the wafers on the susceptor 106. The gas supply system 102 is disposed on the whole reaction chamber 104 and is located above the susceptor 106. The gas supply system 102 may introduce a reaction gas 114 to a position above the wafers on the susceptor 106 in the reaction chamber 104.

In the deposition process, the susceptor 106 rotates around the rotation axis 110 together with the wafers thereon. Meanwhile, the heater 108 heats the wafers on the susceptor 106 through the susceptor 106. When being heated by the heater 108, the reaction gas 114 applied above the wafers on the susceptor 106 by the gas supply system 102 undergoes a reaction to grow a desired deposition layer on the wafer surface. Excessive reactant, undesired products, and waste gas are discharged out of the reaction chamber 104 through a exhaust port 112 at the bottom of the reaction chamber 104.

FIGS. 2A and 2B are a top view and a cross-sectional view of a conventional susceptor. The susceptor 106 generally has a plurality of round recessed portions 116a, 116b, and 116c disposed thereon, as shown in FIG. 2A. As shown in FIG. 2B, the wafers 118a, 118b, and 118c are respectively disposed in the recessed portions 116a, 116b, and 116c, wherein the recessed portions have the same depth.

However, in practice, it is found that when growing chips required by light emitting diode (LED) devices on the susceptor 106 in FIG. 2B, the chips formed on the wafers on the central area of the susceptor 106, for example, wafer 118a and a part of the wafers 118b, especially chips on the wafer 118a at the central position, have an abnormally shorter wavelength, compared with that on the other wafers. Thus, the characteristics of the chips of the same production batch are not consistent, thereby resulting in the yield loss.

Therefore, a heretofore unaddressed need exists in the art to address the aforementioned deficiencies and inadequacies.

### SUMMARY OF THE INVENTION

Accordingly, in one aspect, the present invention is directed to a wafer susceptor and a CVD apparatus, in which a recessed portion is disposed at a central area of the susceptor, so that the susceptor has different thickness distribution. Thus, the problem of uneven temperature of the susceptor can be effectively solved.

In another aspect, the present invention is directed to a wafer susceptor and a CVD apparatus, which can effectively solve the problem that the characteristics and the wavelength of chips placed at a central area of the susceptor are abnormal.

In a further aspect, the present invention is also directed to a wafer susceptor and a CVD apparatus, which can improve the uniformity of temperature distribution of the susceptor, thereby improving the consistency of the characteristics of chips of the same production batch, and achieving the purpose of improving the production yield.

In yet another aspect, the present invention provides a CVD apparatus. The CVD apparatus includes a reaction chamber, a susceptor, a heater, and a gas supply system. The susceptor is disposed in the reaction chamber, and can rotate around a rotation axis. An upper surface of the susceptor is suitable for supporting a plurality of wafers, and a first recessed portion is disposed in a central area of a lower surface of the susceptor. The heater is located below the susceptor, and is used for heating wafers on the susceptor. The gas supply system is used for introducing a reaction gas into the reaction chamber.

According to an embodiment of the present invention, a center of the first recessed portion coincides with a center of the susceptor.

According to another embodiment of the present invention, the center of the first recessed portion deviates from the center of the susceptor.

According to another embodiment of the present invention, the diameter of the first recessed portion is in the range of 1/4 to 4 times of the diameter of each of the wafers.

According to another embodiment of the present invention, the depth of the first recessed portion is in the range of 0.1 mm to the thickness of the susceptor minus 0.5 mm.

According to another embodiment of the present invention, the first recessed portion is an annular recessed portion. In an example, the width of the annular recessed portion is in the range of ⅛ to 2 times of the diameter of each of the wafers. In another example, an average diameter of the annular recessed portion is in the range of ¼ to 2 times of the diameter of each of the wafers, and the average diameter of the annular recessed portion is an average of the inner diameter and the outer diameter of the annular recessed portion.

According to another embodiment of the present invention, the susceptor further includes a plurality of recessed portions and a second recessed portion disposed in an upper surface of the susceptor. The wafers are correspondingly accommodated in the recessed portions, and the second recessed portion is disposed in a bottom of a recessed portion at the central position of the recessed portions. In an example, the diameter of the second recessed portion is smaller than the diameter of each of the wafers, and the depth of the second recessed portion is in the range of 1 μm to 500 μm. In another example, a center of the second recessed portion coincides with a center of a recessed portion at the central position of the recessed portions.

According to another embodiment of the present invention, the first recessed portion has an inclined side, so that the diameter of the first recessed portion gradually increases from a bottom of the first recessed portion towards the lower surface of the susceptor. In an example, the diameter of the first recessed portion at the lower surface of the susceptor is in the range of ¼ to 2 times of the diameter of each of the wafers.

According to another embodiment of the present invention, the CVD apparatus is an MOCVD apparatus.

In another aspect, the present invention further provides a wafer susceptor, which is applicable in a CVD apparatus. The wafer susceptor includes a plurality of first recessed portions and at least one second recessed portion. The first recessed portions are disposed at an upper surface of the wafer susceptor, and are used for supporting a plurality of wafers. The second recessed portion is disposed at an opposite lower surface of the susceptor, and forms a gap space.

By application of the wafer susceptor and the CVD apparatus of the present invention, among other things, the problem of uneven temperature of a susceptor can be effectively solved, and the problem that the characteristics and wavelength of chips placed at a central area of the susceptor are abnormal can be solved, so as to improve the consistency of the characteristics of chips of the same production batch.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment, and wherein:

FIG. 1 is a schematic view of a conventional vertical type CVD apparatus;

FIG. 2A is a top view of a conventional susceptor;

FIG. 2B is a cross-sectional view of the conventional susceptor;

FIG. 3 is a schematic view of a vertical type CVD apparatus according to an embodiment of the present invention;

FIG. 4 is a cross-sectional view of a susceptor according to a first embodiment of the present invention;

FIG. 5 is a cross-sectional view of a susceptor according to a second embodiment of the present invention;

FIG. 6A is a cross-sectional view of a susceptor according to a third embodiment of the present invention;

FIG. 6B is a top view of the susceptor according to the third embodiment of the present invention;

FIG. 7A is a cross-sectional view of a susceptor according to a fourth embodiment of the present invention;

FIG. 7B is a top view of the susceptor according to the fourth embodiment of the present invention; and

FIG. 8 is a cross-sectional view of a susceptor according to a fifth embodiment of the present invention.

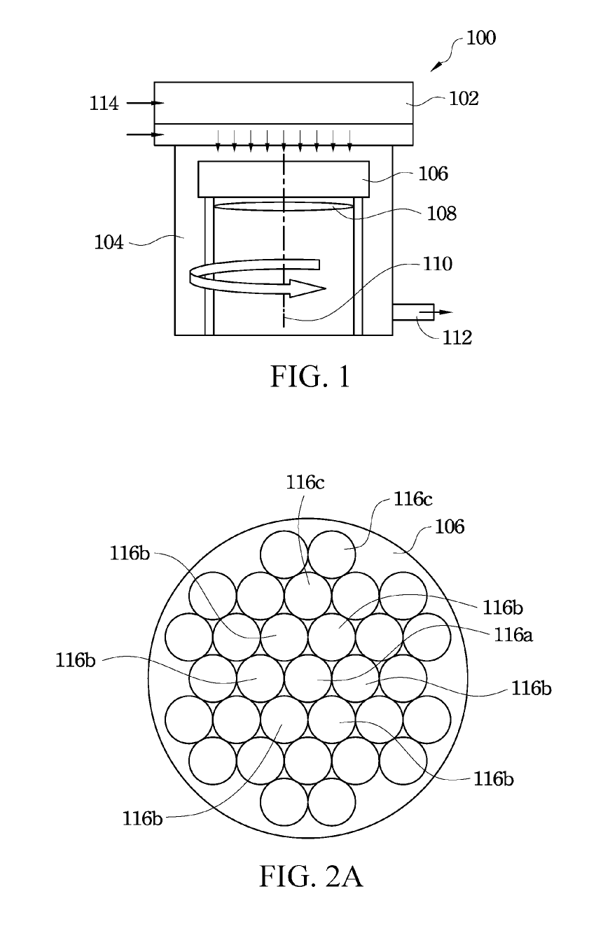

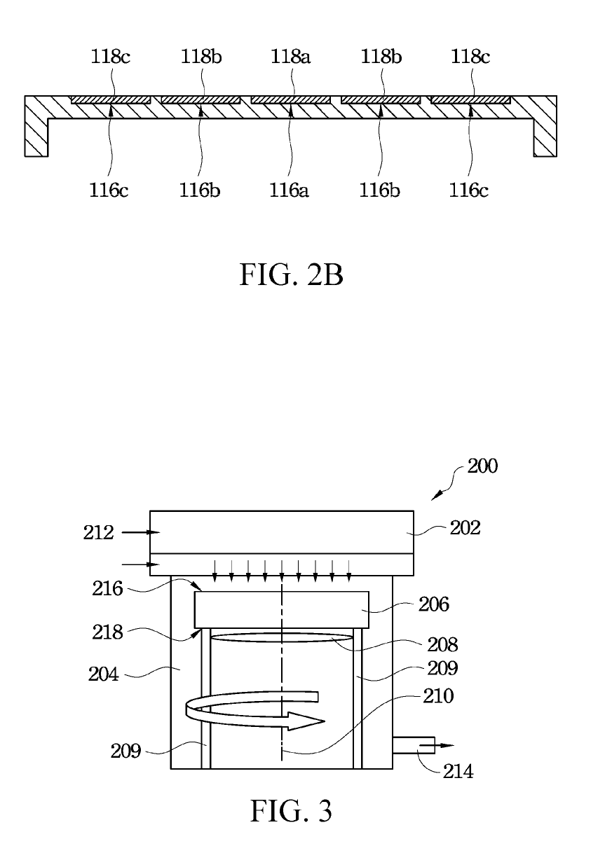

### DETAILED DESCRIPTION OF THE INVENTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

When growing LED chips in a CVD apparatus, chips on wafers at a central area of a susceptor, especially chips on wafers at the central position of the susceptor, have a shorter wavelength than others. Inventors find the problem that the chips on the central area of the susceptor is relatively short, which is because that the reaction temperature of wafers on the central area is higher than that of wafers in other areas in the deposition process. That is to say, a heater of a conventional CVD apparatus cannot heat the wafers on the susceptor evenly. Accordingly, in one aspect, the present invention provides several CVD apparatuses, and susceptors of the CVD apparatuses have different thickness distribution designs, so as to improve the consistency of the characteristics of chips of the same production batch.

FIG. 3 is a schematic view of a vertical type CVD apparatus according to an embodiment of the present invention. In this embodiment, a CVD apparatus 200 includes a reaction chamber 204, a susceptor 206, a heater 208, and a gas supply system 202. In an exemplary embodiment, the CVD apparatus 200 may be, for example, an MOCVD apparatus.

The susceptor 206 is disposed in the reaction chamber 204. The susceptor 206 has an upper surface 216 and a lower surface 218 opposite to the upper surface 216, and the upper surface 216 of the susceptor 206 is used for supporting a plurality of wafers. The heater 208 is disposed in the reaction chamber 204, and is located below the susceptor 206, so as to heat the wafers on the susceptor 206. For example, the heater 208 utilizes the heat provided by a resistance wire, and conducts the heat to the wafers on the susceptor 206 through heat convection, heat radiation, and heat conduction. Moreover, in order to evenly heat the wafers on the susceptor 206, the susceptor 206 may rotate around a rotation axis 210 in the reaction chamber 204, for example, clockwise or counter clockwise, as shown in FIG. 3. The gas supply system 202 is disposed at an upper side of the reaction chamber 204, and is located above the susceptor 206. The gas supply system 202 is used for introducing the reaction gas 212 into the reaction chamber 204, and releasing the reaction gas 212 to surfaces of the wafers on the upper surface 216 of the susceptor 206 from top to bottom.

When a deposition process is carried out in the CVD apparatus 200, the susceptor 206 is driven by a rotating base 209 located below the susceptor 206 to rotate around the rotation axis 210, so that the wafers supported on the susceptor 206 rotate around the rotation axis 210 together. Meanwhile, the heater 208 heats the susceptor 206, so as to further heat the wafers on the upper surface 216 of the susceptor 206 through the conduction of the susceptor 206. At this time, the reaction gas 212 above the susceptor 206 and released by the gas supply system 202 undergoes a reaction, so as to grow a desired deposition layer on surfaces of the wafers on the susceptor 206. Excessive reactants, byproducts, and waste gas are exhausted out of the reaction chamber 204 through a exhaust port 214 at a bottom of the reaction chamber 204.

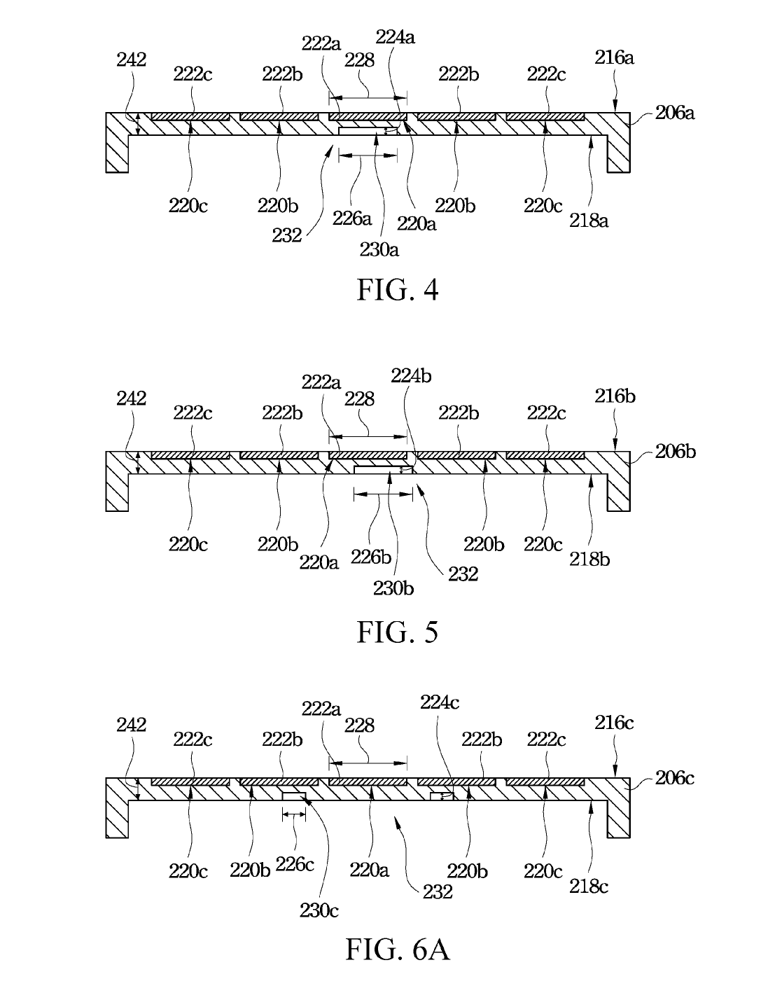

In one aspect of the present invention, the susceptor has different thickness designs to solve the problem of uneven temperature of the susceptor, so as to improve the consistency of the characteristics of the chips. FIG. 4 is a cross-sectional view of a susceptor according to a first embodiment of the present invention. Generally, as shown in FIG. 4, a susceptor 206a includes a plurality of recessed portions 220a, 220b, and 220c, which are recessed in the upper surface 216a of the susceptor 206a, for supporting corresponding wafers. The recessed portions are, for example, round, so as to match the shape of the wafers, and the recessed portions have the same depth. Preferably, the recessed portions have the depth equal to or slightly greater than the thickness of the wafers. The recessed portion 220a is located at the central position of the upper surface 216a of the susceptor 206a, the recessed portions 220b surround a periphery of the recessed portion 220a, and the recessed portions 220c surround a periphery of the recessed portions 220b. As shown in FIG. 4, a wafer 222a may be disposed in the recessed portion 220a at the central position of the susceptor 206a, a plurality of wafers 222b may be disposed in the recessed portions 220b at the periphery of the recessed portion 220a respectively, and a plurality of wafers 222c may be disposed in the recessed portions 220c at the periphery of the recessed portions 220b. The wafers 222a, 222b, and 222c have the same diameter 228.

In this embodiment, a recessed portion 230a is recessed in a central area 232 of a lower surface 218a of the susceptor 206a, so as to form a gap space. The recessed portion 230a is located just below the recessed portion 220a at the central position of the upper surface 216a of the susceptor 206a. In an example, the recessed portion 230a is also round, and has a center coinciding with the center of the susceptor 206a. The diameter 226a of the recessed portion 230a is in the range of ¼ to 4 times of the diameter 228 of the wafer 222a. Furthermore, the depth 224a of the recessed portion 230a is in the range of 0.1 mm to the thickness 242 of the susceptor 206a minus 0.5 mm.

In the susceptor 206a, the recessed portion 230a is disposed on the central area 232 of the lower surface 218a, such that the thickness of the susceptor 206a at the recessed portion 220a at the central position is smaller than the thickness at the other recessed portions 220b and 220c. Therefore, referring to FIGS. 3 and 4, due to the arrangement of the recessed portion 230a, the heat of the heater 208 transferred to the part of the susceptor 206a at the recessed portion 230a and adjacent areas through radiation and convection is reduced, such that the heat received by the part of the susceptor 206a is close to or equal to the heat received by the other parts of the susceptor 206a. In this way, the processing temperature of the wafer disposed on the central area of the upper surface of the susceptor 206a is consistent with the processing temperature of the wafers disposed on the other areas. Thus, the consistency of the characteristics of the chips of the same production batch is improved.

FIG. 5 is a cross-sectional view of a susceptor according to a second embodiment of the present invention. A susceptor 206b of this embodiment has a structure substantially the same as that of the susceptor 206a of the first embodiment, and the difference therebetween lies in that the center of a recessed portion 230b recessed in the central area 232 of a lower surface 218b of a susceptor 206b deviates from the center of the susceptor 206b, which is different from the center of the recessed portion 230a of the susceptor 206a coinciding with the center of the susceptor 206a. In other words, in the susceptor 206b, the recessed portion 230b is not located just below the recessed portion 220a at the central position of an upper surface 216b of the susceptor 206b, but is disposed at a side of the recessed portion 220a at the central position.

In an embodiment, for example, the diameter 226b of the recessed portion 230b is in the range of ¼ to 4 times of the diameter of the wafer 222a. Moreover, for example, the depth 224b of the recessed portion 230b is in the range of 0.1 mm to the thickness 242 of the susceptor 206b minus 0.5 mm.

In the susceptor 206b, the recessed portion 230b in the central area 232 of the lower surface 218b and deviating from the center of the susceptor 206b can not only form a gap space but also make the thickness of the susceptor 206b at the recessed portion 220a at the central position and the adjacent areas smaller than the thickness at the other recessed portions, for example, the thickness at recessed portions 220b and/or 220c. Thus, referring to FIGS. 3 and 5, due to the arrangement of the recessed portion 230b, the heat of the heater 208 transferred to the part of the susceptor 206b at the recessed portion 230b and adjacent areas through radiation and convection is reduced, such that the heat received by the part of the susceptor 206b is close to or equal to the heat received by the other parts of the susceptor 206b. It should be noted that, as the susceptor 206b will rotate with respect to the heater, there will be no problem of uneven temperature distribution caused by the deviating design of the recessed portion 230b below the susceptor 206b. Moreover, through the design of the off-center distance of the recessed portion 230b and the range of the diameter of the recessed portion 230b, the distribution of the temperature gradient of the heated susceptor 206b can be further adjusted. Therefore, the processing temperature of the wafers disposed in the upper surface 216b of the central area and adjacent areas of the susceptor 206b is consistent with the processing temperature of the wafers disposed on the other areas. Thus, the consistency of the characteristics of the chips of the same production batch is improved.

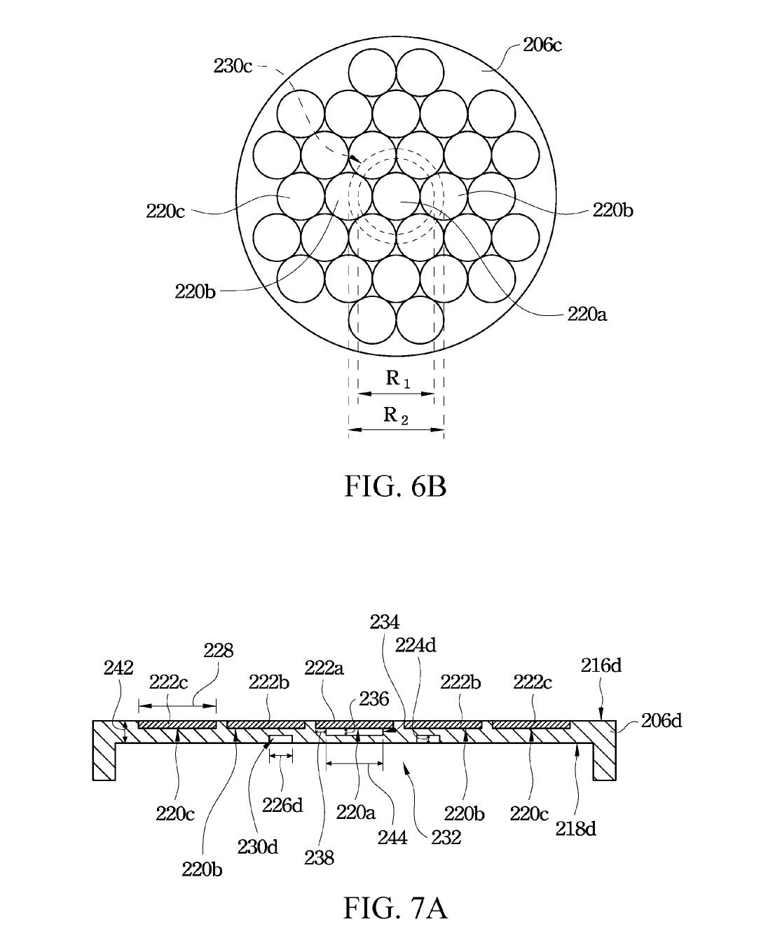

FIGS. 6A and 6B are a cross-sectional view and a top view of a susceptor according to a third embodiment of the present invention respectively. A susceptor 206c of this embodiment has a structure substantially the same as that of the susceptor 206a of the first embodiment, and the difference therebetween lies in that a recessed portion 230c recessed in the central area 232 of a lower surface 218c of the susceptor 206c is an annular recessed portion, which is different from the recessed portion 230a of the susceptor 206a being a round recessed portion, as shown in FIG. 6B. In an embodiment, the center of the annular recessed portion 230c may coincide with the center of the susceptor 206c, as shown in FIG. 6B. In another embodiment, the center of the annular recessed portion 230c may deviate from the center of the susceptor 206c.

In an exemplary embodiment, as shown in FIG. 6A, the width 226c of the annular recessed portion 230c is in the range of ⅛ to 2 times of the diameter 228 of the wafer 222a. Furthermore, referring to FIG. 6B, the annular recessed portion 230c has an average diameter, which is an average of the inner diameter R1 and the outer diameter R2 of the annular recessed portion 230c. In an embodiment, the average diameter of the annular recessed portion 230c is in the range of ¼ to 2 times of the diameter of the wafer 222a. For example, in the embodiment as show in FIG. 6B, the inner diameter R1 and the outer diameter R2 of the recessed portion 230c are larger than the diameter 228 of the wafer 222a; therefore, the recessed portion 230c is disposed below the periphery of the recessed portion 220a of the upper surface 216c, and passes through the part below the recessed portions 220b at the outer side of the recessed portion 220a. In another embodiment, the depth 224c of the recessed portion 230c is in the range of 0.1 mm to the thickness 242 of the susceptor 206c minus 0.5 mm.

In the susceptor 206c, the annular recessed portion 230c disposed on the central area 232 of the lower surface 218c can not only form a gap space, but also make the thickness of the susceptor 206c at the recessed portion 220a at the central position and/or the thickness of the adjacent recessed portions 220b smaller than that at the other recessed portions, for example, the thickness at the recessed portions 220c. Thus, referring to FIGS. 3 and 6A together, due to the arrangement of the annular recessed portion 230c, the heat of the heater 208 transferred to the part of the susceptor 206c at the recessed portions 230c and adjacent areas through radiation and convection is reduced, such that the heat received by the part of the susceptor 206c is close to or equal to the heat received by the other parts of the susceptor 206c. Moreover, through the design of the off-center distance, the average diameter, and the range of the depth of the annular recessed portion 230c, the distribution of the temperature gradient of the heated susceptor 206c can be further adjusted. Therefore, the processing temperature of the wafers disposed on the central area and the adjacent areas of the susceptor 206c is consistent with the processing temperature of the wafers disposed on the other areas. Thus, the consistency of the characteristics of the chips of the same production batch is improved.

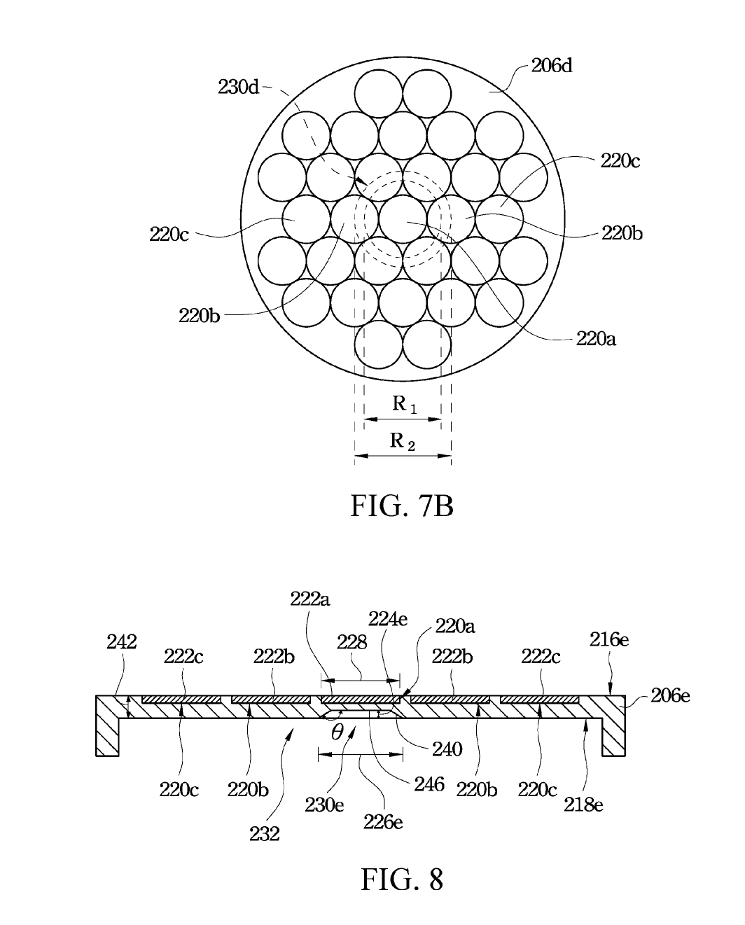

FIGS. 7A and 7B are a cross-sectional view and a top view of a susceptor according to a fourth embodiment of the present invention respectively. A susceptor 206d of this embodiment has a structure substantially the same as that of the susceptor 206c of the third embodiment, and the difference therebetween lies in that, in addition to an annular recessed portion 230d disposed in a lower surface 218d, an upper surface 216d of the susceptor 206d further has a recessed portion 234 disposed therein. The recessed portion 234 is recessed in the bottom of the recessed portion 220a at the central position, as shown in FIG. 7A. In an embodiment, the center of the recessed portion 234 may coincide with the center of the recessed portion 220a, as shown in FIGS. 7A and 7B. In detail, this embodiment may be a multiple-depth recessed portion, which has a first depth for bearing a wafer and a second depth as a gap part below the wafer. In another embodiment, the center of the recessed portion 234 may deviate from the center of the recessed portion 220a at the central position.

In an exemplary embodiment, as shown in FIG. 7A, the depth 226d of the annular recessed portion 230d may be in the range of ⅛ to 2 times of the diameter 228 of the wafer 222a. Similarly, referring to FIG. 7B, the annular recessed portion 230d has an average diameter, in which the average diameter is an average of the inner diameter R1 and the outer diameter R2 of the annular recessed portion 230d. In an embodiment, the average diameter of the annular recessed portion 230d may be in the range of ¼ to 2 times of the diameter of the wafer 222a. Similarly, as shown in FIG. 7B, the inner diameter R1 and the outer diameter R2 of the recessed portion 230d are greater than the diameter 228 of the wafer 222a. Furthermore, the depth 224d of the recessed portion 230d may be in the range of 0.1 mm to the thickness 242 of the susceptor 206d minus 0.5 mm.

Referring to FIG. 7A, as the diameter 244 of the recessed portion 234 is smaller than the diameter 228 of the wafer 222a, the range of the recessed portion 220a for accommodating the wafer 222a can cover the whole recessed portion 234. In an embodiment, the depth 236 of the recessed portion 234 may be in the range of 1 μm to 500 μm. Moreover, a distance 238 between a side of the recessed portion 234 and an adjacent side of the recessed portion 220a may be, for example, 2 mm.

In the susceptor 206d, the annular recessed portion 230d disposed on the central area 232 of the lower surface 218d and the recessed portion 234 disposed in the recessed portion 220a at the central position of the upper surface 216d can not only form two gap spaces, but also make the thickness of the recessed portion 220a at the central position of the susceptor 206d and the thickness of the adjacent recessed portions 220b smaller than the thickness of the other recessed portions, for example, the recessed portions 220c. Therefore, referring to FIGS. 3 and 7A, due to the arrangement of the annular recessed portion 230d and the recessed portion 234, the heat of the heater 208 transferred to the part of the recessed portion 230d and the adjacent areas of the susceptor 206d through radiation and convection is reduced, such that the heat received by the part of the susceptor 206d is close to or equal to the heat received by the other parts of the susceptor 206d. Moreover, through the design of the off-center distance, the average diameter, and the range of the depth of the annular recessed portion 230d, in combination with the arrangement of the recessed portion 234 at the upper surface 216d of the susceptor 206d, the distribution of the temperature gradient of the heated susceptor 206d can be further adjusted. Therefore, the processing temperature of the wafers disposed on the central area and the adjacent areas of the susceptor 206d is consistent with the processing temperature disposed on the other areas. Thus, the consistency of the characteristics of the chips of the same production batch is improved.

FIG. 8 is a cross-sectional view of a susceptor according to a fifth embodiment of the present invention. A susceptor 206e of this embodiment has a structure substantially the same as that of the susceptor 206a of the first embodiment, and the difference therebetween lies in that a recessed portion 230e recessed in the central area 232 of a lower surface 218e of the susceptor 206e has an inclined side 240. That is to say, unlike the side of the recessed portion 230a of the susceptor 206a lessentially perpendicular to the bottom, the inclined side 240 of the susceptor 206e is not perpendicular to a bottom 246, but inclines outwards, such that an angle θ included between the inclined side 240 and the bottom 246 of the susceptor 206e is greater than 90 degrees. Therefore, in the susceptor 206e, the diameter of the recessed portion 230e is increased gradually from the bottom 246 of the recessed portion 230e towards the lower surface 218e of the susceptor 206e, so that the thickness of the part of the susceptor 206e at the recessed portion 230e is increased from the bottom 246 of the recessed portion 230e towards the lower surface 218e of the susceptor 206e.

In an embodiment, the center of the recessed portion 230e may coincide with the center of the susceptor 206e, as shown in FIG. 8. In another embodiment, the center of the recessed portion 230e may deviate from the center of the susceptor 206e.

In an embodiment, the diameter 226e of the recessed portion 230e at the lower surface 218e of the susceptor 206e may be in the range of ¼ to 2 times of the diameter 228 of the wafer 222a. Moreover, the depth 224e of the recessed portion 230e may be in the range of 0.1 mm to the thickness 242 of the susceptor 206e minus 0.5 mm.

In the susceptor 206e, the recessed portion 230e having the inclined side 240 disposed on the central area 232 of the lower surface 218e can not only form a gap space, but also make the thickness of the susceptor 206e at the recessed portion 220a at the central position and the adjacent areas smaller than the thickness at other recessed portions, for example, the thickness at the recessed portions 220b and/or 220c. Therefore, referring to FIGS. 3 and 8 together, due to the arrangement of the recessed portion 230e, the heat of the heater 208 transferred to the part of the susceptor 206e at the recessed portion 230e and the adjacent areas through radiation and convection is reduced, such that the heat received by the part of the susceptor 206e is close to or equal to the heat received by the other parts of the susceptor 206e. Therefore, the processing temperature of the wafers disposed in the upper surface 216e on the central area and the adjacent areas of the susceptor 206e is consistent with the processing temperature disposed on the other areas. Thus, the consistency of the characteristics of the chips of the same production batch is improved.

It can be known from the embodiments, among other things, the present invention has an advantage that the susceptor has different thickness distribution since the susceptor of the CVD apparatus of the present invention has recessed portions disposed on the central area. Thus, the problem of uneven temperature of the susceptor is effectively solved.

It can be known from the embodiments, among other things, the present invention has another advantage that the present invention can effectively solve the problem that the characteristics and the wavelength of chips placed at the central area of the susceptor are abnormal.

It can be known from the embodiments, among other things, the present invention has another advantage that the present invention can improve the uniformity of the temperature distribution of the susceptor, thus improving the consistency of the characteristics of the chips of the same production batch, so as to improve the production yield.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A chemical vapor deposition (CVD) apparatus, comprising:
a reaction chamber;
a susceptor, disposed in the reaction chamber, capable of rotating around a rotation axis, wherein an upper surface of the susceptor is used for supporting a plurality of wafers, and a first recessed portion is disposed at a central area of a lower surface of the susceptor;
a heater, located below the susceptor, for heating the wafers on the susceptor; and
a gas supply system, for introducing a reaction gas into the reaction chamber.

2. The CVD apparatus according to claim 1, wherein a center of the first recessed portion coincide with a center of the susceptor.

3. The CVD apparatus according to claim 1, wherein a center of the first recessed portion deviates from a center of the susceptor.

4. The CVD apparatus according to claim 1, wherein the diameter of the first recessed portion is in a range of ¼ to 4 times of the diameter of each of the wafers.

5. The CVD apparatus according to claim 1, wherein the depth of the first recessed portion is in a range of 0.1 mm to the thickness of the susceptor minus 0.5 mm.

6. The CVD apparatus according to claim 1, wherein the first recessed portion is an annular recessed portion.

7. The CVD apparatus according to claim 6, wherein the width of the annular recessed portion is in a range of ⅛ to 2 times of the diameter of each of the wafers.

8. The CVD apparatus according to claim 6, wherein an average diameter of the annular recessed portion is in a range of ¼ to 2 times of the diameter of each of the wafers, and the average diameter of the annular recessed portion is an average of the inner diameter and the outer diameter of the annular recessed portion.

9. The CVD apparatus according to claim 6, wherein the susceptor further comprises a plurality of recessed portions and a second recessed portion disposed in the upper surface, the wafers are correspondingly accommodated in the recessed portions, and the second recessed portion is disposed in a bottom of a recessed portion at the central position of the recessed portions.

10. The CVD apparatus according to claim 9, wherein the diameter of the second recessed portion is smaller than the diameter of each of the wafers, and the depth of the second recessed portion is in a range of 1 μm to 500 μm.

11. The CVD apparatus according to claim 9, wherein a center of the second recessed portion coincides with a center of the recessed portion at the central position of the recessed portions.

12. The CVD apparatus according to claim 1, wherein the first recessed portion has an inclined side, so that the diameter of the first recessed portion gradually increases from a bottom of the first recessed portion to the lower surface.

13. The CVD apparatus according to claim 12, wherein the diameter of the first recessed portion at the lower surface is in a range of ¼ to 2 times of the diameter of each of the wafers.

14. The CVD apparatus according to claim 1, wherein the CVD apparatus is a metal-organic CVD (MOCVD) apparatus.

15. A wafer susceptor, applicable in a chemical vapor deposition (CVD) apparatus, comprising:
a plurality of first recessed portions, disposed at an upper surface of the wafer susceptor, for supporting a plurality of wafers; and
at least one second recessed portion, disposed at an opposite lower surface of the wafer susceptor, for forming a gap space.

16. The wafer susceptor according to claim 15, wherein a center of the second recessed portion coincides with a center of the wafer susceptor.

17. The wafer susceptor according to claim 15, wherein a center of the second recessed portion deviates from a center of the wafer susceptor.

18. The wafer susceptor according to claim 15, wherein the second recessed portion is an annular recessed portion.

19. The wafer susceptor according to claim 15, further comprising a third recessed portion, disposed in the upper surface, and disposed in a bottom of a first recessed portion at the central position of the first recessed portions.

20. The wafer susceptor according to claim 15, wherein the second recessed portion has an inclined side, so that the diameter of the second recessed portion gradually increases from a bottom of the second recessed portion to the lower surface.
